(19) United States
(12) Patent Application Publication
(10) Pub. No.: US 2025/0318275 A1
(43) Pub. Date: Oct. 9, 2025

(54) SILICON CARBIDE POWER SEMICONDUCTOR DEVICE HAVING FOLDED CHANNEL AREA, AND MANUFACTURING METHOD THEREFOR

(71) Applicant: Trinno Technology Co., Ltd., Seoul (KR)

(72) Inventors: Kwang Hoon OH, Seoul (KR); Soo Seong KIM, Seoul (KR); Jin Young JUNG, Seoul (KR); Chongman YUN, Seoul (KR)

(21) Appl. No.: 18/859,994

(22) PCT Filed: Apr. 11, 2023
(86) PCT No.: PCT/KR2023/004848

§ 371 Date: Jun. 20, 2025

(30) Foreign Application Priority Data
Apr. 26, 2022 (KR) 10-2022-0051215

(51) Int. Cl. H10D 89/60

(52) U.S. Cl. CPC H10D 89/611

(57) ABSTRACT

A silicon carbide power semiconductor device having a folded channel area, and a manufacturing method therefor are disclosed. The power semiconductor device comprises a gate protection circuit unit arranged between a source metal and a gate electrode, wherein the gate protection circuit unit comprises: an embedded diode which is formed such that a first conductive ion injection area and a second conductive ion injection area are alternately connected in multiple stages to a polysilicon layer insulated by an insulation film layer formed on the upper side surface of a semiconductor substrate, and which has one side end electrically connected to the source metal and another side end electrically connected to the gate electrode; and one or more floating metal layers for shorting the first conductive ion injection area and the second conductive ion injection area, which are adjacent to each other in the embedded diode.

### FIELD OF THE INVENTION

The present invention relates to silicon carbide power semiconductor having folded channel area and method for manufacturing therefor.

### BACKGROUND

Silicon carbide is gaining attention as a material for power semiconductor devices that can achieve high breakdown voltage. Silicon carbide power semiconductor devices have the advantage of being able to control large currents due to their high breakdown voltage.

Particularly for high voltage and/or high current applications, power semiconductor devices made of wide bandgap semiconductors such as silicon carbide (SiC), aluminum nitride (AlN), and gallium nitride (GaN) have the advantage of operating at higher temperatures, having lower on-resistance, and being able to be implemented in a smaller chip size than semiconductor devices made of silicon (Si).

However, unlike silicon materials, power semiconductor devices made of silicon carbide have the problem of forming a compound in the form of SixCyO at the SiO₂/SiC interface during the growth of the gate insulating film, which acts as an interface trap.

These problems are expressed as interface trapped density, and high interface trapped density causes increased channel resistance due to decreased channel mobility of power semiconductor devices, unstable threshold voltage, increased on-resistance of power semiconductor devices, etc., which deteriorate the performance of power semiconductor devices.

In addition, in order to reduce the high channel resistance, the driving voltage of silicon carbide power semiconductor devices needs to be around 15 to 20 V. This driving voltage is high compared to the driving voltage of silicon power semiconductor devices, which is around 10 V, and there is also the problem that the driving circuit of silicon power semiconductor devices cannot be universally used.

In addition, since the interface characteristics of SiO₂/SiC in silicon carbide power semiconductor devices deteriorate in inverse proportion to the gate insulating film thickness, the gate insulating film thickness is applied at the level of 500 Angstroms, which is thinner than the level of 1000 Angstroms in silicon power semiconductor devices.

As a result, silicon carbide power semiconductor devices have the problems that a gate insulation withstand voltage in proportion to the gate insulating film thickness is inferior to that of silicon materials, and also the gate insulation withstand voltage has asymmetry in the forward mode and reverse modes.

The description of the technology behind this invention is provided for the purpose of understanding the background of the invention and is not intended to be a statement of the prior art known to those of ordinary skill in the art.

### DETAILED DESCRIPTION OF THE INVENTION

### Technical Objectives

The present invention is intended to provide a silicon carbide power semiconductor device having a folded channel region formed therein which can improve the performance of the device by increasing the effective channel width and thereby reducing the channel resistance, and a method of manufacturing the same.

The present invention is intended to provide a silicon carbide power semiconductor device having a folded channel region formed therein which can solve the asymmetry problem of gate insulation withstand voltage in forward mode and reverse mode by having an asymmetric gate protection circuit, and a method of manufacturing the same.

Other objects of the present invention will be easily understood through the following description.

### Technical Solution

According to one aspect of the present invention, there is provided a power semiconductor device having a planar gate structure, including a gate protection circuit arranged between a source metal and a gate electrode, wherein the gate protection circuit includes a built-in diode formed by a first conductive ion implantation region and a second conductive ion implantation region that are alternately connected in multi-stage manner in a polysilicon layer formed to be insulated by an insulating film layer formed on the upper surface of a semiconductor substrate, one end of which is electrically connected to the source metal, and the other end of which is electrically connected to the gate electrode and one or more floating metal layers formed to short the first conductive ion implantation region and the second conductive ion implantation region adjacent to each other in the built-in diode, wherein the floating metal layers are arranged so that the magnitudes of a forward protection voltage and a reverse protection voltage of the gate protection circuit are different from each other.

The channel region of the power semiconductor device is formed as a folded channel region, wherein the folded channel region is formed in a convexo-concave shape in a width direction of the channel region by repeatedly spacing a plurality of trench grooves parallel to a longitudinal direction of the channel region on the upper surface layer of the semiconductor substrate.

The gate protection circuit may be formed in a gate pad region.

The floating metal layers may be not electrically connected to the source metal and the gate electrode.

The folded channel region formed in the convexo-concave shape by successively arranging channel regions perpendicular to each other in the width direction of the channel region to have a step difference may be arranged such that adjacently arranged channel regions are arranged to have a plane shape with different positions, and when current is applied, the current flows through the plane in which each channel region is positioned to a source region formed in the corresponding channel region.

The source region may be formed on the upper surface region of the semiconductor substrate in the convexo-concave shape corresponding to the shape of the folded channel region.

The trench groove may be formed to a depth that is relatively shallower than a thickness of a first conductive contact region formed in a first conductive body region formed on the upper surface region of the semiconductor substrate.

The trench groove may be formed to extend in the longitudinal direction of the channel region in the upper surface layer of the JFET region, channel region, and source region of the semiconductor substrate.

The power semiconductor device may be a MOSFET or an insulated gate bipolar transistor.

Aspects, features, advantages other than above described will be apparent from the following drawings, claims and detailed description.

### Effects of the Invention

The silicon carbide power semiconductor device according to the embodiment of the present invention has the advantage of promoting high performance of the device by widening the effective channel width to have low channel resistance.

In addition, it has the advantage of solving the asymmetry problem of the gate insulation withstand voltage in forward mode and reverse mode by providing an asymmetrical gate protection circuit.

Advantages obtainable in the present invention are not limited to the mentioned above, and other advantages not mentioned can be clearly understood by those skilled in the art from the description below.

### BRIEF DESCRIPTION OF ACCOMPANYING DRAWINGS

FIG. 1 exemplarily illustrates a frontal cross-sectional view of a silicon carbide MOSFET having a planar gate structure according to a prior art, and a graph showing the asymmetric characteristics of the gate insulation withstand voltage in the forward mode/reverse mode;

FIG. 2 is a frontal and lateral A-A′ cross-sectional view of a silicon carbide MOSFET according to one embodiment of the present invention;

FIG. 3 is a frontal and lateral B-B′ view of a silicon carbide MOSFET according to one embodiment of the present invention;

FIG. 4 is a frontal and top view of a silicon carbide MOSFET according to one embodiment of the present invention;

FIG. 5 and FIG. 6 exemplarily illustrate a silicon carbide MOSFET equipped with a gate protection circuit according to one embodiment of the present invention; and

FIG. 7 and FIG. 8 exemplarily illustrate a method for manufacturing a silicon carbide MOSFET according to one embodiment of the present invention.

### MODE FOR INVENTION

The invention can be modified in various forms and specific embodiments will be described and shown below. However, the embodiments are not intended to limit the invention, but it should be understood that the invention includes all the modifications, equivalents, and replacements belonging to the concept and the technical scope of the invention. In describing the present invention, if it is determined that a detailed description of a related known technology may obscure the gist of the present invention, the detailed description thereof will be omitted.

Terms such as first, second, etc., may be used to refer to various elements, but, these elements should not be limited due to these terms. These terms will be used to distinguish one element from another element.

The terms used in the following description are intended to merely describe specific embodiments, but not intended to limit the invention. An expression of the singular number includes an expression of the plural number, so long as it is clearly read differently. The terms such as “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers refer to like elements throughout the specification.

Relative terms, such as “below” or “above” or “upper” or “lower” or “horizontal” or “lateral” or “vertical” may be used herein to describe-one element, layer or region's relationship to another elements, layers or regions as illustrated in the Figures. It will be understood that relative terms are intended to encompass different orientations of the device in addition to the orientation depicted in the Figures.

Hereinafter, an embodiment of the present invention will be described in detail with reference to the accompanying drawings. However, in the following description, power MOSFET made of silicon carbide will be mainly described, but it should be understood that the technical concept of the present invention may be applied and expanded to various types of semiconductor devices such as IGBT in the same or similar manner.

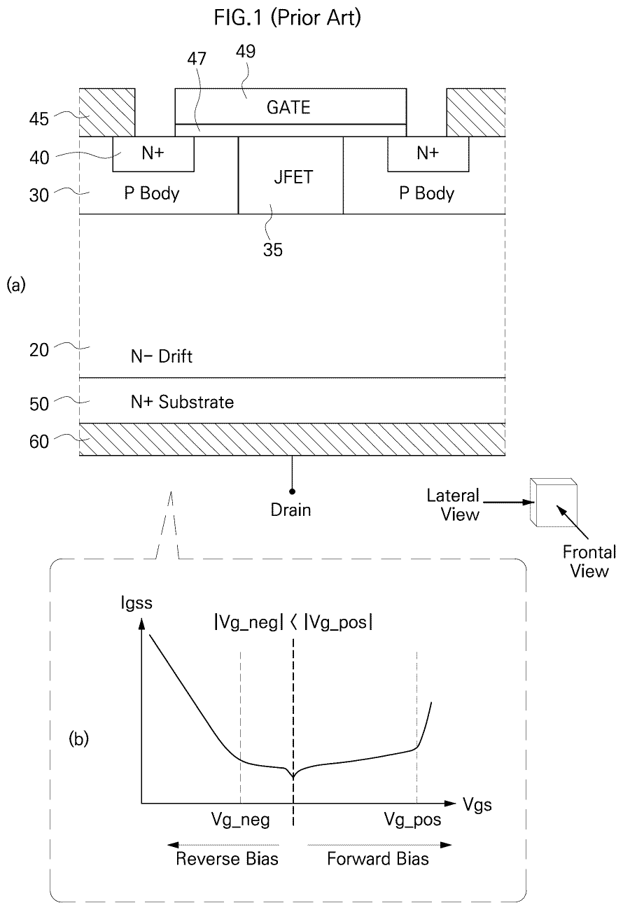

FIG. 1 exemplarily illustrates a frontal cross-sectional view of a silicon carbide MOSFET having a planar gate structure according to a prior art, and a graph showing the asymmetric characteristics of the gate insulation withstand voltage in the forward mode/reverse mode.

Referring to (a) of FIG. 1, the silicon carbide MOSFET has an N+ conductive silicon carbide substrate 50, and the silicon carbide substrate 50 is formed as a semiconductor substrate, which is an epitaxial substrate, by forming an N− conductive drift region 20 in the upper surface of the silicon carbide substrate 50.

In the surface region of the semiconductor substrate (i.e., the upper surface region of the drift region 20), a P conductive body region 30 is formed spaced apart from the JFET region 35, and an N+ conductive source region 40 is formed spaced apart from the JFET region 35 in the upper portion of the body region 30 (i.e., the region adjacent to the upper surface of the semiconductor substrate).

To form a channel, a gate electrode 49 is formed on the source region 40 and the JFET region 35, which are formed spaced apart from each other, and a gate insulating film 47 is interposed therebetween for insulation.

In addition, a source metal 45 is formed on the upper surface of the semiconductor substrate to be spaced apart from the gate electrode 49 and electrically connected to the source region 40, and a drain metal 60 is formed on the lower surface of the N+ conductive silicon carbide substrate 50.

When the gate insulating film 47 of a silicon carbide MOSFET is grown, a compound in the form of SixCyO is formed at the SiO₂/SiC interface, which causes problems due to reduced channel mobility such as increased channel resistance, unstable threshold voltage, and increased on-resistance of the power semiconductor device. In addition, in order to reduce the high channel resistance, a high driving voltage is required compared with a silicon-based power semiconductor device, which prevents the drive circuit of the silicon-based power semiconductor device from being universally used.

To solve this problem, a device structure with low channel resistance is required.

In addition, since the interface characteristics of the SiO₂/SiC of the silicon carbide MOSFET are inversely proportional to the thickness of the gate insulating film 47, unlike a silicon-based semiconductor device, a thin thickness of about 500 angstroms is applied, and as illustrated in (b) of FIG. 1, and the gate insulation withstand voltage is asymmetrical in forward mode and reverse mode, as illustrated in (b) of FIG. 1.

In a silicon carbide MOSFET, leakage current due to the Fowler-Nordheim (FN) tunneling effect of electrons flows through the gate insulating film on top of the JFET region 35 under forward gate bias, and leakage current due to the FN tunneling effect of holes flows through the gate insulating film 47 on the channel region under reverse gate bias (see Ximing Chen, et, al., Deep Understanding of Negative Gate Voltage Restriction for SiC MOSFET Under Wide Temperature Range, IEEE TRANSACTIONS ON POWER ELECTRONICS, VOL. 36, NO. 8, August 2021).

As a result, silicon carbide planar MOSFETs are generally very vulnerable to gate overvoltage, and the gate insulation withstand voltage is set to −5 V<Vgs<20 V. Therefore, considering the operating characteristics of such the silicon carbide MOSFET, an asymmetrical protection circuit for gate protection needs to be provided.

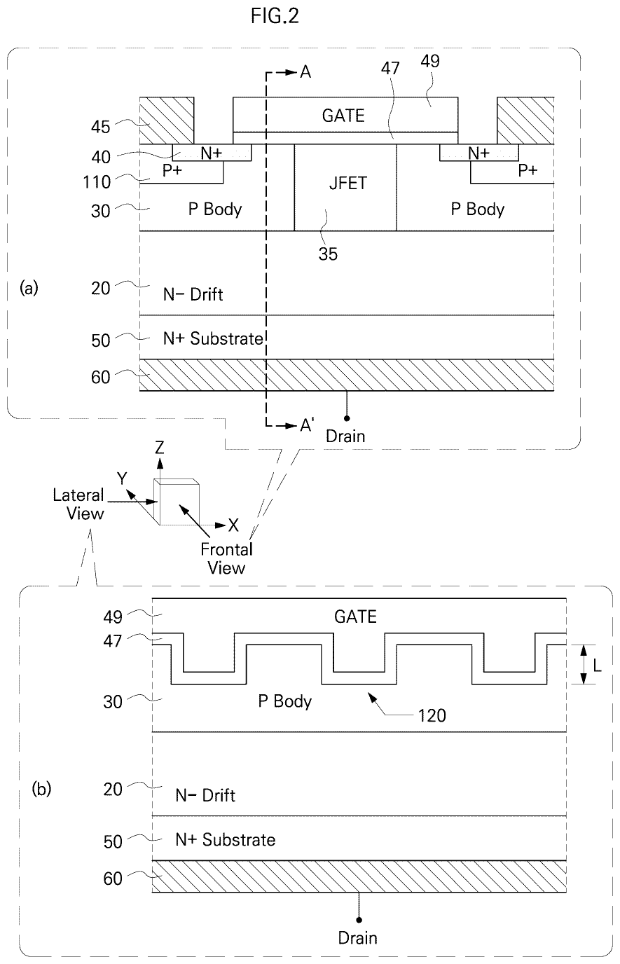

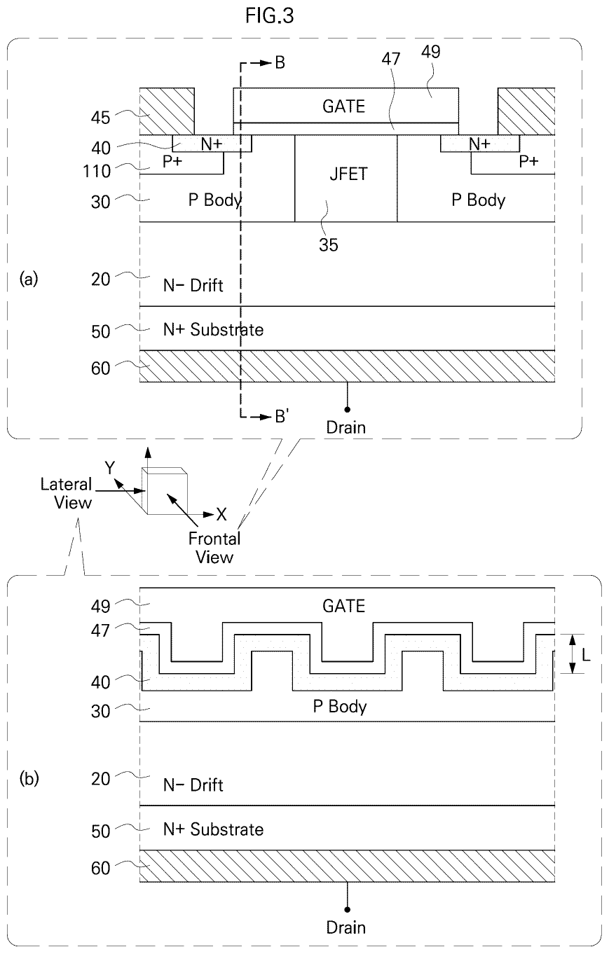

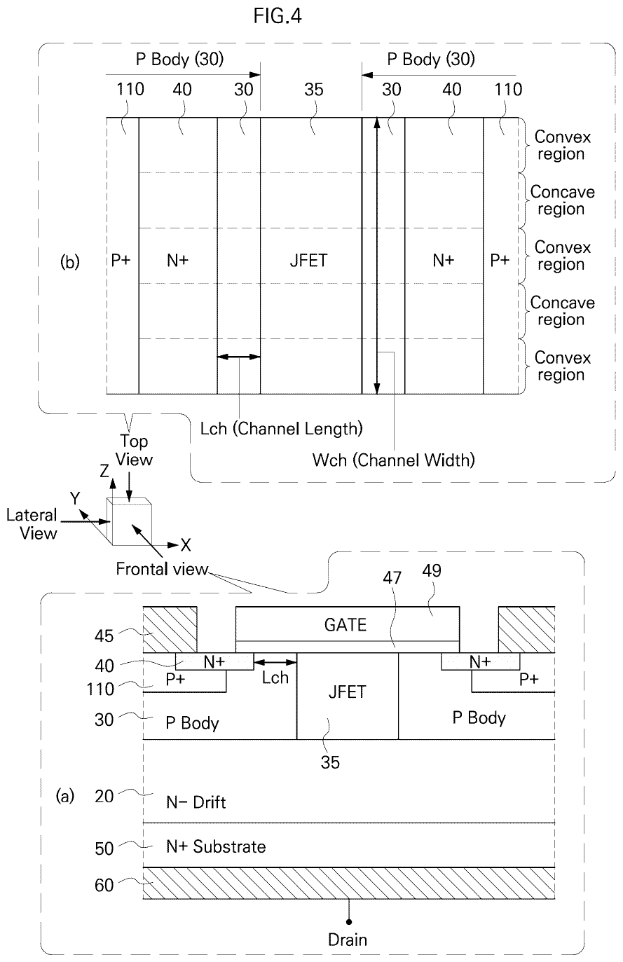

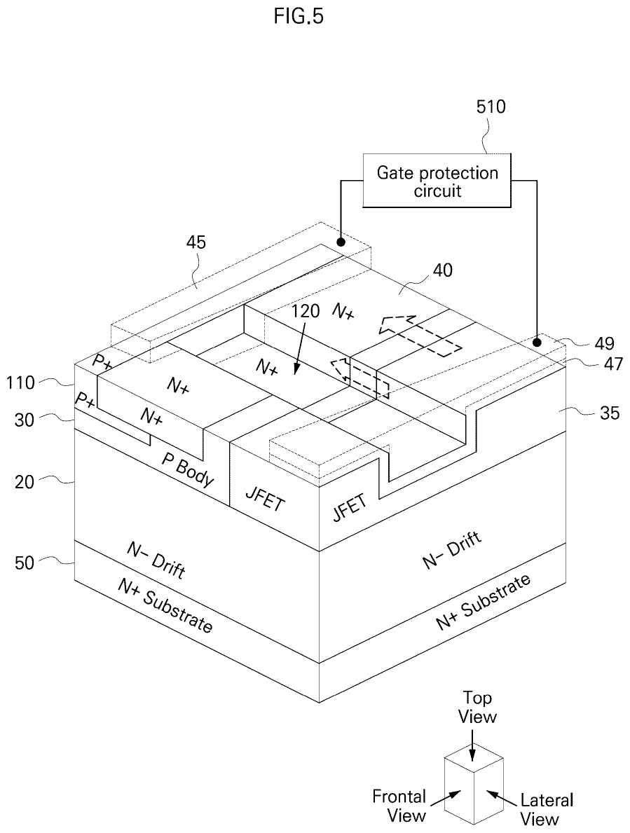

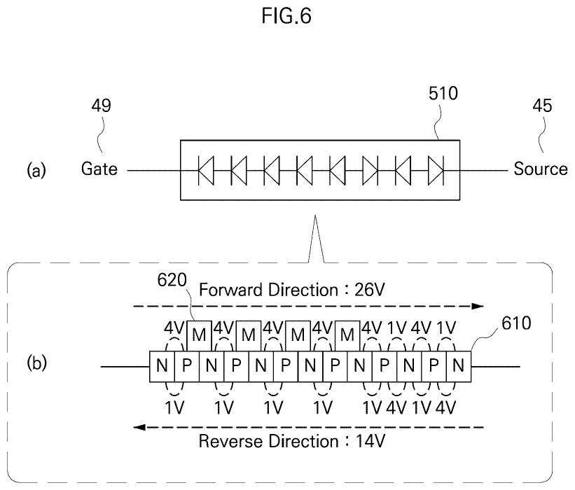

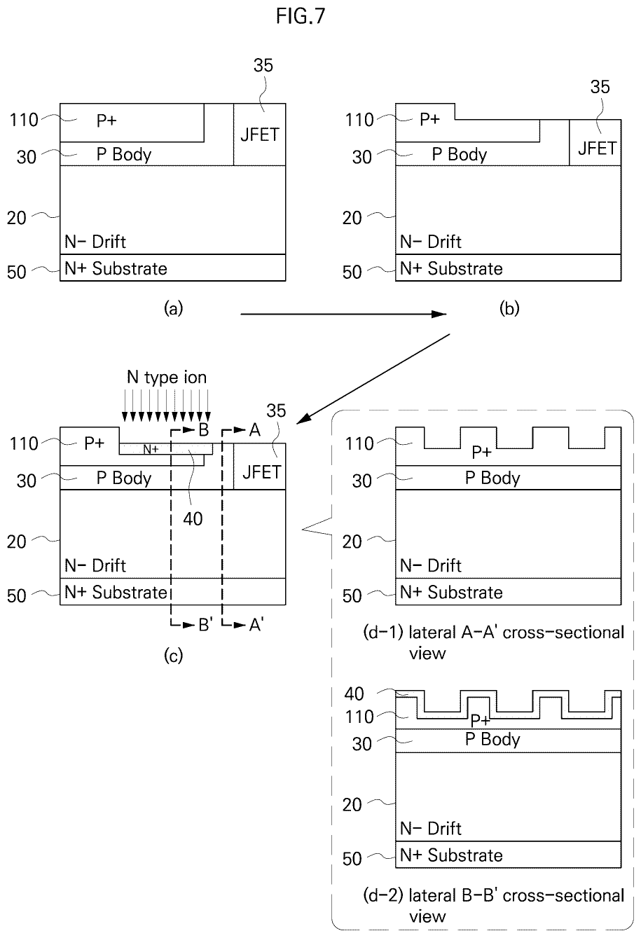

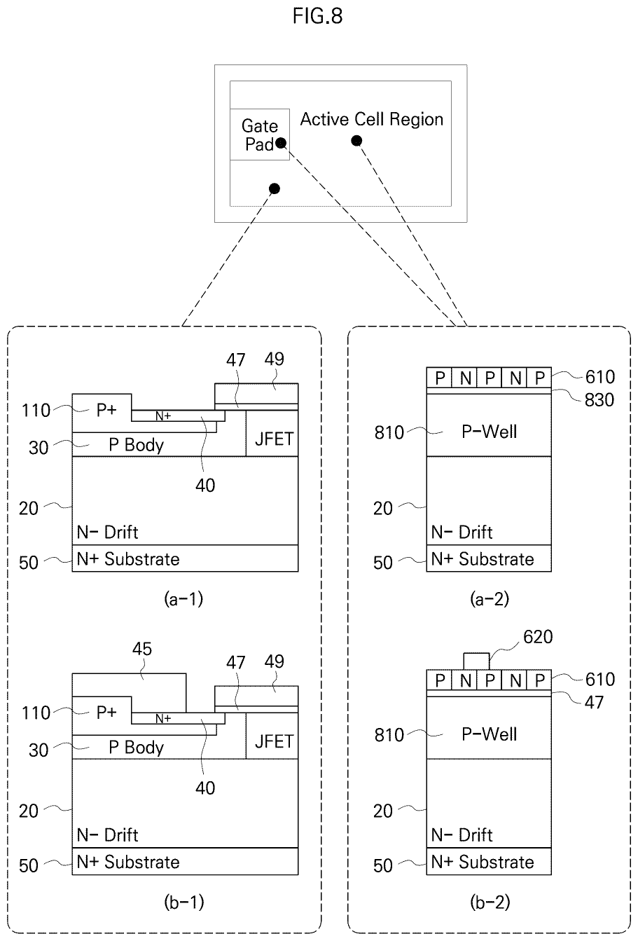

FIG. 2 is a frontal and lateral A-A′ cross-sectional view of a silicon carbide MOSFET according to one embodiment of the present invention, FIG. 3 is a frontal and lateral B-B′ view of a silicon carbide MOSFET according to one embodiment of the present invention, and FIG. 4 is a frontal and top view of a silicon carbide MOSFET according to one embodiment of the present invention. FIG. 5 and FIG. 6 exemplarily illustrate a silicon carbide MOSFET equipped with a gate protection circuit according to one embodiment of the present invention, and FIG. 7 and FIG. 8 exemplarily illustrate a method for manufacturing a silicon carbide MOSFET according to one embodiment of the present invention. In this disclosure, for the convenience of explanation, a cross-section corresponding to the XZ plane, as illustrated in FIG. 2 and the like will be referred to as a frontal cross-section, a cross-section corresponding to the YZ plane is referred to as a lateral cross-section, and a cross-section corresponding to the XY plane is referred to as a top cross-section.

Referring to (a) of FIG. 2 and (a) of FIG. 3 in which the cross-sectional shape in the frontal direction is illustrated, a silicon carbide MOSFET includes an N+-conductive silicon carbide substrate 50, and the silicon carbide substrate 50 is formed as a semiconductor substrate, which is an epitaxial substrate, by forming an N− conductive drift region 20 in the upper surface of the silicon carbide substrate 50. The silicon carbide substrate 50 may be, for example, a 4H-SiC substrate of a hexagonal close-packed (HCP) structure containing nitrogen (N) as an N-type impurity.

In the surface region of the semiconductor substrate (i.e., the upper surface region of the drift region 20), a P conductive body region 30 is formed spaced apart from the JFET region 35, and a P+ conductive contact region 110 is formed spaced apart from the JFET region 35 in the upper portion of the body region 30 (i.e., the region adjacent to the upper surface of the semiconductor substrate). An N+ conductive source region 40 is formed continuously on the upper portion of the contact region 110 and the upper portion of the body region 30, but spaced apart from the JFET region 35 to form a channel region.

A gate electrode 49 is formed on the source regions 40 spaced apart across the JFET region to form a channel, and the gate insulating film 47 is interposed therebetween for insulation.

In addition, a source metal 45 is formed on the semiconductor substrate so as to be electrically connected to the source region 40 while being spaced apart from the gate electrode 49, and a drain metal 60 is formed on the lower surface of the N+ conductive silicon carbide substrate 50.

For the silicon carbide MOSFET illustrated in (a) of FIG. 2 and (a) of FIG. 3 in which the frontal cross-sectional view is illustrated, a cross-sectional view of A-A′ passing vertically between the JFET region 35 and the source region 40 (i.e., channel region) is illustrated in (b) of FIG. 2, and a cross-sectional view of B-B′ passing vertically through the source region 40 formed below the gate electrode 49 is illustrated in (b) of FIG. 3.

Referring to (b) of FIG. 2 showing the A-A′ cross-sectional view at the channel region, trench grooves 120 of a predetermined depth are spaced apart on the upper surface of the semiconductor substrate where the source region 40 and the contact region 110 are formed. The trench groove 120 may be formed with a depth that is relatively shallower than the thickness of the contact region 110 formed on the upper surface of the semiconductor substrate.

The trench groove 120 is formed to extend in the depth direction of the lateral cross-sectional view (i.e., the longitudinal direction Lch of the channel region, and the X-axis direction shown), and as illustrated in FIG. 5, the extension length of the trench groove 120 may be, for example, a length corresponding to the distance between the distal ends of the source regions 40 formed to be spaced apart from each other across the JFET region 35 (i.e., the distance between the ends of the source regions 40 bounded by the channel region).

The width of the trench groove 120 may be formed with a length of, for example, 1 μm to several μm, and the spacing between the trench grooves 120 may also be formed with a length of, for example, 1 μm to several um accordingly. By forming the depth of the trench groove 120 and/or the density of the trench groove 120 to be large, the channel resistance can be relatively reduced.

The gate insulating film 47 is formed with a predetermined thickness on the upper surface of the semiconductor substrate formed in convexo-concave shape by forming the trench groove 120, and the gate electrode 49 is formed on the gate insulating film 47 so as to be insulated from the source region 40. The gate electrode 49 may be formed with, for example, polysilicon, etc.

As described above, in the silicon carbide MOSFET according to the present embodiment, the plurality of trench grooves 120 are repeatedly formed in a spaced apart manner parallel to the longitudinal direction Lch of the channel region, thereby forming a folded channel region in convexo-concave shape in which orthogonal channel regions are successively arranged with a step difference (see FIGS. 2 to 5).

Here, as illustrated in FIG. 5, the adjacently arranged channel regions do not exist on the same plane, and when conducting, current flows to the source region existing on each plane.

The folded channel region has the characteristic in that the channel width Wch is relatively increased compared to the horizontal channel region provided in the conventional planar-type silicon carbide MOSFET.

For example, since the channel width can be relatively increased by the length that the channel region extends in the vertical direction, when the channel width of the conventional silicon carbide MOSFET is Wch, the folded channel region illustrated in (b) of FIG. 2 becomes Wch+6 L, increasing the channel width by 6 L.

This allows the channel width to be increased in various ways depending on the depth and spacing of the folded channel region.

Therefore, the silicon carbide MOSFET according to the present embodiment has the advantage of forming a folded channel region with a three-dimensional structure to increase the channel width, thereby reducing the on-resistance, conduction losses having characteristics proportional to the channel width.

In contrast, referring to (b) of FIG. 3, which shows a cross-sectional view taken along B-B′ at a location including the source region 40, the source region 40 of a predetermined thickness to contact the trench groove 120 is formed at the bottom of the trench groove 120 in a shape corresponding to the shape of the folded channel region.

Hereinafter, the process of forming the folded channel region will be briefly described with reference to FIG. 7.

First, as shown in (a) of FIG. 7, a P conductive body region 30 and an N conductive JFET region 35 are formed respectively through P conductive ion implantation, N conductive ion implantation, and activation on the upper surface of the semiconductor substrate, and a P+ conductive contact region 110 is formed in the upper portion of the body region 30 to be spaced apart from the JFET region 35 (see (a) of FIG. 7).

Then, as shown in (b) of FIG. 7, in order to form the folded channel region, a suitable mask is used to selectively etch the upper surface of the semiconductor substrate, thereby forming trench grooves 120 having a predetermined depth spaced apart from each other.

The trench grooves 120 that form the upper surface of the semiconductor substrate into a convexo-concave shape are formed to extend in the depth direction (i.e., the longitudinal direction of the channel region) of the lateral cross-section view, as shown in (d-1) and (d-2) of FIG. 7. The extension length of the trench groove 120 may be, for example, a length corresponding to the distance between the distal ends of the source regions 40 formed to be spaced apart from each other across the JFET region 35.

Since the junction depth of the body region 30 is relatively reduced by forming the trench groove 120, the formation depth of the trench groove 120 may be predetermined to a depth that does not affect the breakdown voltage characteristics of the silicon carbide MOSFET.

Next, as shown in (c) of FIG. 7, the N+ conductive source region 40 is formed continuously on the upper portion of the contact region 110 and the upper portion of the body region 30 and spaced apart from the JFET region 35 by ion implantation and activation of the N+ conductive ions. To form the source region 40 on the sidewall of the etched trench groove 120, N+ conductive ions may be implanted obliquely into the corresponding region.

By the process described above, a lateral cross-sectional view of the channel region A-A′ where the source region 40 is not formed is illustrated in (d-1) of FIG. 7, and a lateral cross-sectional view of the B-B′ where the source region 40 is formed is illustrated in (d-2) of FIG. 7.

As described above, the gate insulation withstand voltage of the silicon carbide MOSFET has a problem of asymmetry in the forward mode and the reverse mode.

To solve this problem, the silicon carbide MOSFET according to the present embodiment is provided with a gate protection circuit 510 to protect against gate over voltage and gate oscillation.

The gate protection circuit 510 is arranged between the gate electrode 49 and the source metal 45, as illustrated in FIG. 5. In addition, as illustrated in FIGS. 6 and 8, the gate protection circuit 510 is formed as built-in diodes being insulated by an insulating film layer 830 that is formed together in the step of forming the gate insulating film 47 and having alternating multi-stage bonding of N conductive ion implanted regions and P conductive ion implanted regions in the polysilicon layer 610 formed together in the step of forming the gate electrode 49. One end of the built-in diode is connected to the gate electrode 49, and the other end of the built-in diode is connected to the source metal 45. The insulating film layer 830 may be, for example, a gate oxide insulating film, or may be a field oxide (FOX) when forming an edge termination region.

The gate protection circuit 510 may be configured as an asymmetrical protection circuit considering the asymmetrical gate insulation withstand voltage characteristics of the silicon carbide MOSFET.

For convenience of explanation, as illustrated in (b) of FIG. 6, assuming that the turn-on voltage of P/N is 1 V and the breakdown voltage of N/P is 4 V in the asymmetric protection circuit included in the gate protection circuit 510 of the silicon carbide MOSFET, the forward protection voltage can be set to 26 V and the reverse protection voltage can be set to −14 V. That is, the gate protection circuit 510 according to the present embodiment has a feature in which the protection voltage is different depending on the forward or reverse direction.

To be implemented as the asymmetric protection circuit, one or more floating metal layers 620, which are not electrically connected to the gate electrode 49 and the source metal 45 and which function for a different purpose from the field plate of the edge termination region, are formed to short the adjacent P conductive region and N conductive region.

The gate protection circuit 510 may be arranged in the gate pad region, as illustrated in FIG. 8, or may be arranged in an idle space of the active cell region, for efficient space utilization of the silicon carbide MOSFET.

Hereinafter, the process of forming the gate protection circuit 510 will be briefly described with reference to FIG. 8.

First, as shown in (a-2) of FIG. 8, the insulating film layer 830 is formed on the upper surface of a P conductive well region 810 formed through P conductive ion implantation and activation on the upper surface region of the semiconductor substrate, and built-in diodes are formed on the insulating film layer 830.

The built-in diodes are formed by forming the polysilicon layer 610 on the insulating film layer 830, and forming the polysilicon layer 610 in a shape in which the N conductive ion implantation region and the P conductive ion implantation region are alternately bonded in the multi-stage manner.

Each of the well region 810, the insulating film layer 830, and the polysilicon layer 610 may be formed together in each of the processes for forming the P conductive body region 30, the gate insulating film 47, and the gate electrode 49 shown in (a-1) of FIG. 8.

Next, as shown in (b-2) of FIG. 8, in order to form the asymmetric protection circuit by the built-in diodes formed by the P conductive ion implantation and N conductive ion implantation, one or more floating metal layers 620 are formed to short the adjacent P conductive region and N conductive region. The floating metal layer 620 is formed so as not to be electrically connected to the gate electrode 49 and the source metal 45.

For example, the floating metal layer 620 may be formed together in the process of forming the source metal 45 shown in (b-1) of FIG. 8.

While the silicon carbide power semiconductor device has been described herein using the example of MOSFET, it is appreciated that the technical idea of the present invention may be applied and extended to various types of power semiconductor devices such as an insulated gate bipolar transistor (IGBT) in the same or similar manner.

As described above, the silicon carbide power semiconductor device according to the embodiments of the present invention has the characteristics of improving the performance of the device by increasing the channel mobility to have a low channel resistance, and solving the problem of asymmetry of gate insulation withstand voltage in forward mode and reverse mode by having the asymmetrical gate protection circuit.

Although the present invention has been described above with reference to embodiments thereof, it will be understood by those skilled in the art that various modifications and changes may be made to the present invention without departing from the spirit and scope of the present invention as set forth in the claims below.

1. A power semiconductor device having a planar gate structure, comprising:
a gate protection circuit arranged between a source metal and a gate electrode,
wherein the gate protection circuit comprises
a built-in diode formed by a first conductive ion implantation region and a second conductive ion implantation region that are alternately connected in multi-stage manner in a polysilicon layer formed to be insulated by an insulating film layer formed on the upper surface of a semiconductor substrate, one end of which is electrically connected to the source metal, and the other end of which is electrically connected to the gate electrode; and
one or more floating metal layers formed to short the first conductive ion implantation region and the second conductive ion implantation region adjacent to each other in the built-in diode,
wherein the floating metal layers are arranged so that the magnitudes of a forward protection voltage and a reverse protection voltage of the gate protection circuit are different from each other.

2. The power semiconductor device of claim 1, wherein a channel region of the power semiconductor device is formed as a folded channel region,
wherein the folded channel region is formed in a convexo-concave shape in a width direction of the channel region by repeatedly spacing a plurality of trench grooves parallel to a longitudinal direction of the channel region on the upper surface layer of the semiconductor substrate.

3. The power semiconductor device of claim 1, wherein the gate protection circuit is formed in a gate pad region.

4. The power semiconductor device of claim 1, wherein the floating metal layers are not electrically connected to the source metal and the gate electrode.

5. The power semiconductor device of claim 2, wherein the folded channel region formed in the convexo-concave shape by successively arranging channel regions perpendicular to each other in the width direction of the channel region to have a step difference are arranged such that adjacently arranged channel regions are arranged to have a plane shape with different positions, and when current is applied, the current flows through the plane in which each channel region is positioned to a source region formed in the corresponding channel region.

6. The power semiconductor device of claim 5, wherein the source region is formed on the upper surface region of the semiconductor substrate in the convexo-concave shape corresponding to the shape of the folded channel region.

7. The power semiconductor device of claim 2, wherein the trench groove is formed to a depth that is relatively shallower than a thickness of a first conductive contact region formed in a first conductive body region formed on the upper surface region of the semiconductor substrate.

8. The power semiconductor device of claim 2, wherein the trench groove is formed to extend in the longitudinal direction of the channel region in the upper surface layer of the JFET region, channel region, and source region of the semiconductor substrate.

9. The power semiconductor device of claim 1, wherein the power semiconductor device is a MOSFET.

10. The power semiconductor device of claim 1, wherein the power semiconductor device is an insulated gate bipolar transistor.
